(19) United States
(12) Patent Application Publication
(10) Pub. No.: US 2009/0081864 A1
(43) Pub. Date: Mar. 26, 2009

(54) SiC Film for Semiconductor Processing

(75) Inventors: Laura M. Matz, Macungie, PA (US); Ping Jiang, Plano, TX (US); William Wesley Dostalik, Plano, TX (US); Ting Tsui, Markham (CA)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/859,119

(22) Filed: Sep. 21, 2007

(51) Int. Cl. H01L 21/4763

(52) U.S. Cl. 438/637; 257/E21.495

(57) ABSTRACT

A silicon carbide (SiC) film for use in backend processing of integrated circuit manufacturing, is generated by including hydrogen in the reaction gas mixture. This SiC containing film is suitable for integration into etch stop layers, dielectric cap layers and hard mask layers in interconnects of integrated circuits.

### FIELD OF THE INVENTION

This invention relates to the field of integrated circuits. More particularly, this invention relates to integrated circuits with dual damascene copper interconnects and low-k dielectrics.

### BACKGROUND OF THE INVENTION

It is well known that integrated circuits (ICs) consist of electrical components such as transistors, diodes, resistors and capacitors built into the top layer of a semiconductor substrate. It is also well known that these components are electrically connected to form useful circuits by metal interconnects, separated by dielectric materials. Dielectric materials with dielectric constants lower than silicon dioxide, collectively known as “low-k dielectrics,” as well as other dielectric materials, including dielectric materials containing nitrogen, are used in interconnect fabrication. Photoresists used in interconnect fabrication are commonly known as amplified resists. A problem arises with the use of dielectric layers containing nitrogen, in combination with low-k dielectrics and amplified resists. This phenomenon is known as resist poisoning. Resist poisoning can distort the photolithographically defined features of interconnects, resulting defective or non-functional interconnects, which in turn cause circuit failures or reliability problems, or both.

Another problem lies in the etch selectivity of dielectric films used as etch stop layers or cap layers. Lower etch selectivities (defined as the ratio of low-k etch rate to etch stop or cap layer etch rate) necessitate thicker films than desired, causing increased process cost and complexity, and decreased IC performance.

Another problem lies in the lack of compatibility of some dielectric films with the metals used in the interconnects, necessitating interposed layers between the problematic dielectric films and the metal layers.

Yet another problem lies in the poor surface adhesion of some dielectric materials used in interconnect fabrication to other layers also used in interconnect fabrication.

Films containing silicon carbide (SiC) have been proposed as a dielectric material for use as an etch stop and hard mask layer. Attempts to generate these SiC containing films for semiconductor use have resulted in thin films with undesirable material properties such as poor thermal stability, high porosity, etc. Implementations of these films have also resulted in high process cost and complexity.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

This invention comprises a method for forming an integrated circuit comprising a silicon carbide containing (SiC) film suitable for use in fabrication of interconnects for integrated circuits. The SiC containing film of this invention is formed using various gases, including 100 to 2000 sccm hydrogen, resulting in a stoichiometry of 45 to 55 atomic percent silicon. The SiC containing film of this invention may be implemented in a PMD cap layer, in a contact hard mask layer, in a via etch stop layer, in a dielectric cap layer, in a metal hard mask layer, or in a trench etch stop layer.

### DESCRIPTION OF THE VIEWS OF THE DRAWING

FIG. 1 is a cross-section of an integrated circuit embodying this invention.

FIG. 2 is a cross-section of interconnects in an integrated circuit implementing this invention in a PMD cap layer.

FIG. 3 is a cross-section of interconnects in an integrated circuit implementing this invention in contact hard mask layer.

FIG. 4 is a cross-section of interconnects in an integrated circuit implementing this invention in a via etch stop layer.

FIG. 5 is a cross-section of interconnects in an integrated circuit implementing this invention in a dielectric cap layer.

FIG. 6 is a cross-section of interconnects in an integrated circuit implementing this invention in a via etch hard mask layer.

FIG. 7 is a cross-section of interconnects in an integrated circuit implementing this invention in a trench etch hard mask layer.

FIG. 8 is a cross-section of interconnects in an integrated circuit implementing this invention in a trench etch stop layer.

### DETAILED DESCRIPTION

Silicon carbide containing thin films are generated in a plasma reactor using gases that include tri-methyl silane, helium and 100 to 2000 standard cubic centimeters per minute (sccm) of hydrogen. The stoichiometry of the resulting SiC containing film is 45 to 55 atomic percent silicon, 45 to 55 atomic percent carbon, and other elements (if present) such as oxygen, nitrogen, hydrogen, etc. The improved properties of these SiC containing films result from the inclusion of the hydrogen gas in the reaction gases that flow into the plasma reactor. The SiC containing thin films properly generated with this additional hydrogen gas exhibit improved thermal stability and porosity compared to SiC containing films generated without additional hydrogen, and are suitable for integration into integrated circuit interconnects.

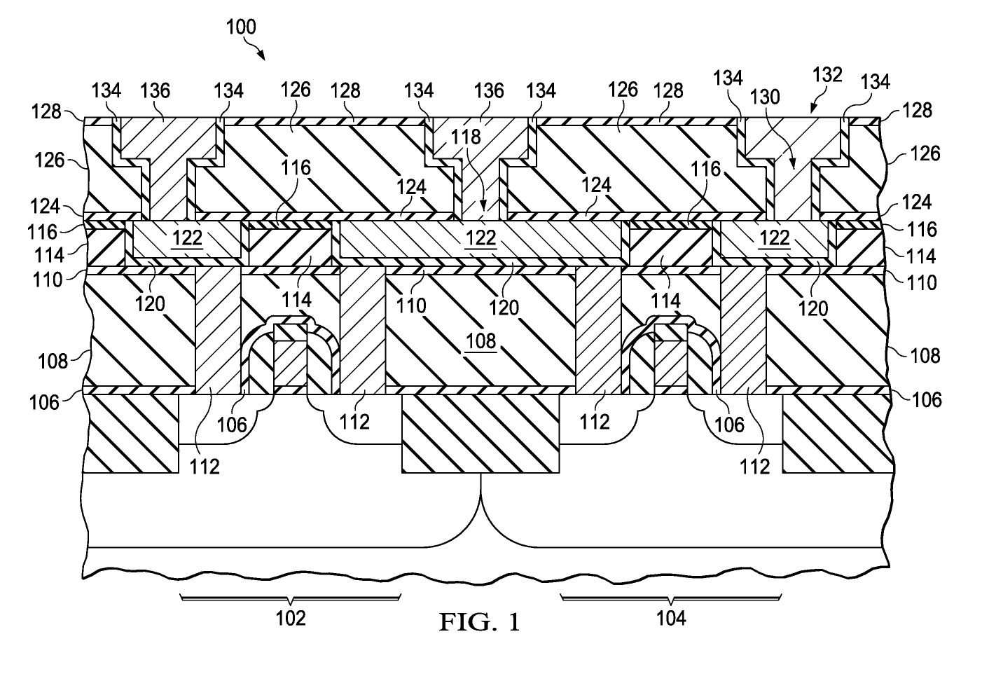

FIG. 1 is a cross-section of an integrated circuit embodying this invention. An integrated circuit (100) includes an n-channel MOS transistor (102) and a p-channel MOS transistor (104). On the transistors is deposited a pre-metal dielectric liner (PMD liner) (106), typically silicon nitride, followed by a pre-metal dielectric (PMD) (108), typically phosphorus doped silicon dioxide, followed by a PMD cap layer (110) incorporating a SiC containing film according to an embodiment of the instant invention. Contacts (112) are formed through the PMD cap (110), PMD (108) and PMD liner (106) to connect the transistors (102, 104) to interconnects. On the contacts and PMD stack is deposited a layer of inter-metal 1 dielectric (IMD-1) (114), typically composed of low-k dielectric material, followed by a dielectric cap layer (116) or hard mask layer (not shown in this figure), or both, incorporating a SiC containing film generated per this invention. Metal level 1 interconnects (118) include a metal 1 liner (120) and metal 1 fill (122), typically copper, are formed using well known methods. Over the metal 1 interconnects and ILD-1 is deposited a via 1 etch stop layer (124) incorporating a SiC containing film generated per this invention, followed by deposition of an inter-level 2 dielectric (ILD-2) (126), typically composed of low-k dielectric material, followed by a dielectric cap layer (128) or hard mask layer (not shown in this figure), or both, incorporating a SiC containing film generated per this invention. Via 1 (130) and metal level 2 interconnects (132) including a metal 2 liner (134) and metal 1 fill (136), typically copper, are formed using well known methods.

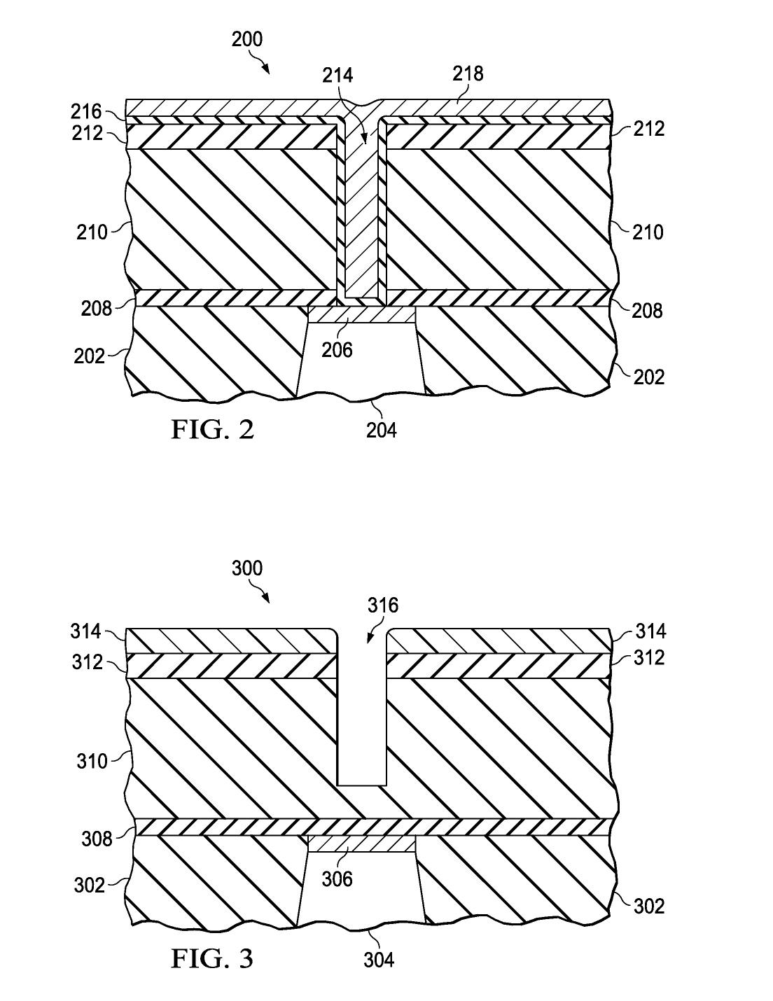

FIG. 2 is a cross-section of interconnects in an integrated circuit implementing this invention in a PMD cap layer. An integrated circuit (200) includes field oxide (202), typically STI or LOCOS, active area (204), and may include optional metal silicide (206), typically titanium silicide, cobalt silicide or nickel silicide. Over the field oxide and active area is deposited a pre-metal dielectric liner (PMD liner) (208), typically silicon nitride, followed by deposition of a pre-metal dielectric (PMD) (210), typically phosphorus doped silicon dioxide, followed by a PMD cap layer (212) including a SiC containing film generated according to an embodiment of the instant invention. This is advantageous because the SiC containing film will not contribute to resist poisoning, as will nitrogen containing films, which improves fabrication yield. Contact holes (214) are etched through the PMD cap, PMD and PMD liner using well known processes. An optional contact liner metal (216) may be deposited in the contact holes and on the top surface of the PMD cap layer. Contact fill metal (218), typically tungsten, is deposited in the contact holes and on the top surface of the PMD cap layer or contact liner metal, if present. After deposition of the contact fill metal, the excess contact fill metal and contact liner metal, located on the top surface of the PMD cap, are removed by etching or chemical mechanical polishing (CMP) or a combination of both. The use of SiC as generated by this invention in the PMD cap layer is advantageous because the selectivity of the contact metal and contact liner removal process to SiC as generated by this invention is higher than other PMD cap materials used in interconnect fabrication, which results in more uniform topography after the contact metal removal process is completed in integrated circuits using this invention in the PMD cap layer. In another embodiment, a PMD cap layer may be composed solely of SiC as generated according to an embodiment of the instant invention.

FIG. 3 is a cross-section of interconnects in an integrated circuit implementing this invention in a contact hard mask layer. An integrated circuit (300) includes field oxide (302), typically STI or LOCOS, active area (304), and may include optional metal silicide (306), typically titanium silicide, cobalt silicide or nickel silicide. Over the field oxide and active area is deposited a pre-metal dielectric liner (PMD liner) (308), typically silicon nitride, followed by deposition of a pre-metal dielectric (PMD) (310), typically phosphorus doped silicon dioxide. Over the PMD is deposited a contact hard mask layer (312) including a SiC containing film generated according to an embodiment of the instant invention. Contact regions are defined by depositing photoresist (314) and patterning it using well known photolithographic techniques. The cost and complexity of the photolithographic process is determined, in part, by the thickness of the hard mask layer, and the time required to etch through it to define the contact holes (316) in the PMD (310). The thickness of the hard mask layer is, in part, determined by the etch rate selectivity of the hard mask layer relative to the dielectric material immediately beneath it, in this case, the PMD. SiC containing films generated according to this invention used as hard mask layers demonstrate superior etch rate selectivity relative to the dielectric materials commonly used in PMD layers compared to other hard mask layers used in interconnect fabrication. Thus, the incorporation of SiC containing films generated according to this invention in contact hard mask layers is advantageous because it allows the use of simpler, less costly photolithographic processes to define the contact regions. Another factor in the thickness of the hard mask is the adhesion of the top surface of the hard mask to the photolithographic layers deposited on the hard mask, for example the bottom anti-reflection coating (BARC). The SiC containing films generated according to this invention exhibit superior adhesion to photolithographic materials compared to other hard mask films used in interconnect fabrication, obviating the need for a separate adhesion layer in the hard mask, which is frequently employed in interconnect fabrication. The elimination of a separate adhesion layer reduces the overall thickness of the hard mask and consequently contributes to decreased cost and complexity in the photolithographic process. In another embodiment, a contact hard mask layer may be comprised solely of SiC generated according to an embodiment of the instant invention.

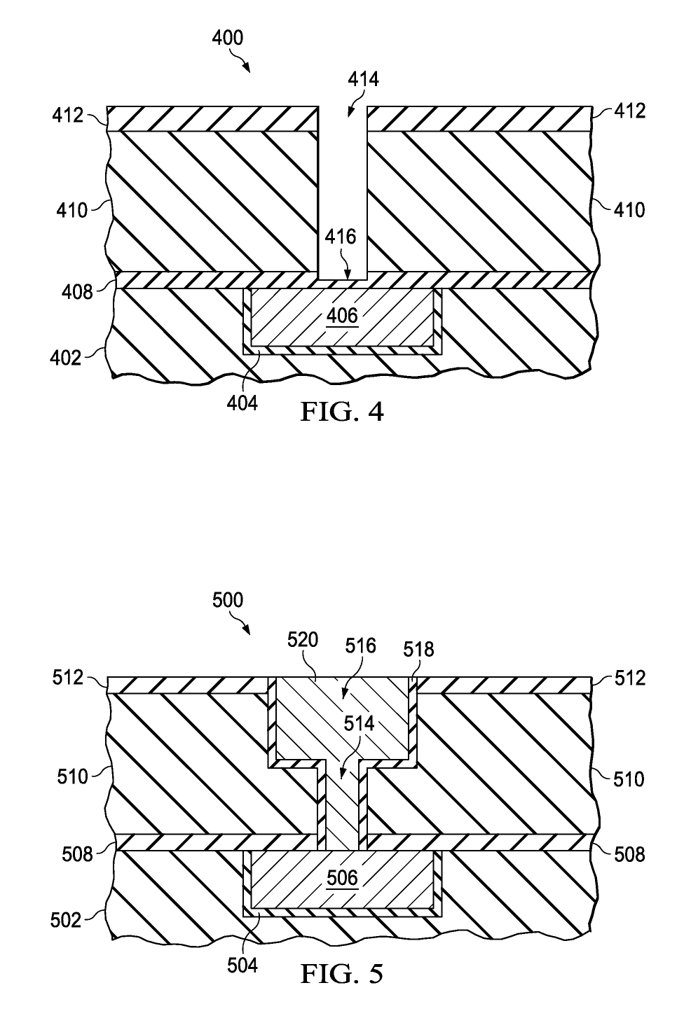

FIG. 4 is a cross-section of interconnects in an integrated circuit implementing this invention in a via etch stop layer, shown here as fabricated in a via-first process sequence. An integrated circuit (400) includes an lower inter-level dielectric (ILD) (402), often composed of low-k material, in which has been fabricated a metal interconnect line including a metal liner (404) and metal fill (406). Over the lower inter-level dielectric (402) and metal interconnect line is deposited a via etch stop (408) including a SiC containing film generated according to an embodiment of the instant invention. Over the via etch stop layer is deposited an upper ILD (410), also often composed of low-k material, followed by an optional hard mask layer (412). A via region has been defined using well known photolithographic techniques, and a via hole (414) has been etched through the hard mask layer (412) and upper inter-level dielectric (410) into the via etch stop layer (408). The incorporation of a SiC containing film generated per this invention in the via etch stop layer (408) is advantageous because the etch rate selectivity of SiC containing films generated per this invention demonstrate superior etch rate selectivity relative to dielectric materials commonly used in ILD layers compared to other etch stop layers used in interconnect fabrication; superior etch rate selectivity allows the use of a thinner etch stop layer, which results in less lateral capacitive coupling between adjacent metal lines, which improves circuit performance. Another advantage of incorporation of a SiC containing film generated per this invention in a via etch stop layer is the SiC containing film will not contribute to resist poisoning of the via or trench pattern. Another advantage of incorporation of a SiC containing film generated per this invention in a via etch stop layer is that SiC can be deposited directly on copper metal lines, unlike films containing oxygen commonly used in interconnect fabrication, eliminating the need for a buffer layer. Depositing SiC directly on copper metal lines is further advantageous because the bottom surface of the SiC inhibits copper movement associated with via stress migration, which causes reliability problems, more than other films employed in direct contact with copper in interconnect fabrication. In another embodiment, a via etch stop layer may be composed solely of SiC generated according to an embodiment of the instant invention. It will be apparent to practitioners in integrated circuit fabrication that the embodiments of a SiC containing film generated according to this invention in a via etch stop layer, as related here, can be implemented in any level of interconnect in an integrated circuit.

FIG. 5 is a cross-section of interconnects in an integrated circuit implementing this invention in a dielectric cap layer. An integrated circuit (500) includes a lower inter-level dielectric (ILD) (502), often composed of low-k material, in which has been fabricated a lower metal interconnect line including a lower metal liner (504) and lower metal fill (506), typically copper. Over the lower inter-level dielectric (502) and metal interconnect line is deposited a via etch stop layer (508). Over the via etch stop layer is deposited an upper ILD (510), also often composed of low-k material, followed by an ILD cap layer (512) composed of a SiC containing film generated according to an embodiment of the instant invention. A metal via (514) and upper metal line (516), including an upper metal liner (518) and upper metal fill (520), typically copper, are fabricated in the via etch stop layer, upper ILD and ILD cap layer. The use of SiC generated according to this invention in the ILD cap layer is advantageous because SiC does not contribute to resist poisoning, as do other films employed in interconnect fabrication which contain nitrogen, which improves fabrication yield. A further advantage is manifested during the copper CMP process; SiC containing films generated according to this invention exhibit superior durability to copper CMP than other films employed for ILD cap layers in interconnect fabrication, which results in more uniform thickness of the upper metal lines, which improves circuit performance. Superior durability to copper CMP allows a thinner ILD cap layer, which provides another advantage in less lateral capacitive coupling between adjacent metal lines, which also improves circuit performance. In another embodiment, an ILD cap layer may be composed solely of SiC generated according to an embodiment of the instant invention. It will be apparent to practitioners of integrated circuit fabrication that the embodiments of a SiC containing film generated according to this invention in an ILD cap layer, as related here, can be implemented in any level of interconnect in an integrated circuit.

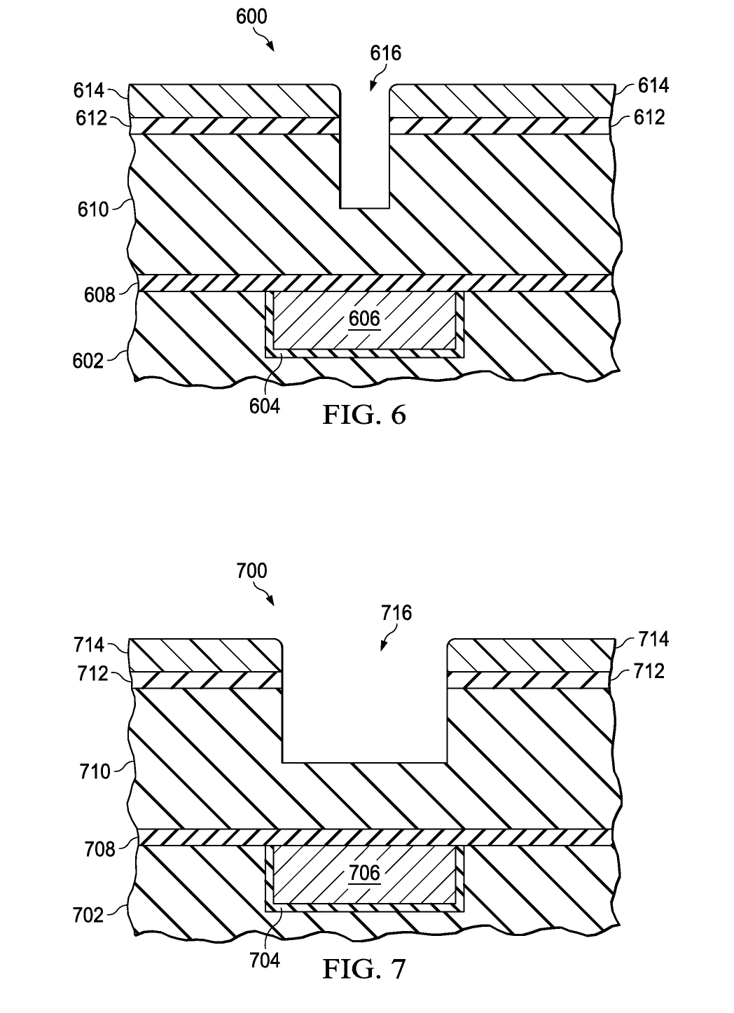

FIG. 6 is a cross-section of interconnects in an integrated circuit implementing this invention in a via etch hard mask layer, shown here as fabricated in a via-first process sequence. An integrated circuit (600) includes a lower inter-level dielectric (ILD) (602), often composed of low-k material, in which has been fabricated a lower metal interconnect line including a lower metal liner (604) and lower metal fill (606), typically copper. Over the lower inter-level dielectric (602) and metal interconnect line is deposited a via etch stop layer (608). Over the via etch stop layer is deposited an upper ILD (610), also often composed of low-k material. Over the upper ILD (610) is deposited a via etch hard mask layer (612) including a SiC containing film generated according to an embodiment of the instant invention. Via regions are defined by depositing photoresist (614) and patterning it using well known photolithographic techniques. As discussed above, the cost and complexity of the photolithographic process is determined, in part, by the thickness of the via etch hard mask layer, and the time required to etch through it to define the via holes (616) in the upper ILD (610). The thickness of the via etch hard mask layer is, in part, determined by the etch rate selectivity of the via etch hard mask layer relative to the dielectric material immediately beneath it, in this case, the upper ILD. SiC containing films generated according to this invention used as via etch hard mask layers demonstrate superior etch rate selectivity relative to the dielectric materials commonly used in ILD layers, especially low-k dielectric materials, compared to other via etch hard mask layers used in interconnect fabrication. Thus, the incorporation of SiC containing films generated according to this invention in via etch hard mask layers is advantageous because it allows the use of simpler, less costly photolithographic processes to define the via regions. Another factor in the thickness of the via etch hard mask is the adhesion of the top surface of the via etch hard mask to the photolithographic layers deposited on the hard mask, for example the bottom anti-reflection coating (BARC). The SiC containing films generated according to this invention exhibit superior adhesion to photolithographic materials compared to other via etch hard mask films in use in interconnect fabrication, obviating the need for a separate adhesion layer in the via etch hard mask, which is frequently employed in interconnect fabrication. The elimination of a separate adhesion layer reduces the overall thickness of the hard mask and consequently contributes to decreased cost and complexity in the photolithographic process. Yet another advantage of incorporating a SiC containing film generated according to this invention in a via etch hard mask layer is the SiC will not contribute to resist poisoning, unlike other films commonly used for via etch hard mask layers in interconnect fabrication. In another embodiment, a via etch hard mask layer may be composed solely of SiC as according to an embodiment of the instant invention. It will be apparent to practitioners of integrated circuit fabrication that the embodiments of a SiC containing film generated according to this invention in a via etch hard mask layer, as related here, can be implemented in any level of interconnect in an integrated circuit.

FIG. 7 is a cross-section of interconnects in an integrated circuit implementing this invention in a trench etch hard mask layer, shown here as fabricated in a trench-first process sequence. An integrated circuit (700) includes a lower inter-level dielectric (ILD) (702), often composed of low-k material, in which has been fabricated a lower metal interconnect line including a lower metal liner (704) and lower metal fill (706), typically copper. Over the lower inter-level dielectric (702) and metal interconnect line is deposited a via etch stop layer (708). Over the via etch stop layer is deposited an upper ILD (710), also often composed of low-k material. Over the upper ILD (710) is deposited a trench etch hard mask layer (712) including a SiC containing film generated according to an embodiment of the instant invention. Trench regions are defined by depositing photoresist (714) and patterning it using well known photolithographic techniques. A trench (716) is etched through the trench etch hard mask layer and into the upper ILD (710). The advantages of incorporating a SiC containing film generated according to this invention in a trench hard mask layer are similar to those of incorporating said SiC containing film in a via etch hard mask layer, as discussed above, and are listed here:

allows use of simpler, less costly photolithographic processes to define the via regions;

eliminates need for a separate adhesion layer in the via etch hard mask; and

does not contribute to resist poisoning.

In another embodiment, a trench etch hard mask layer may be composed solely of SiC generated according to an embodiment of the instant invention. It will be apparent to practitioners of the integrated circuit fabrication that the embodiments of a SiC containing film generated according to this invention in a trench etch hard mask layer, as related here, can be implemented in any level of interconnect in an integrated circuit.

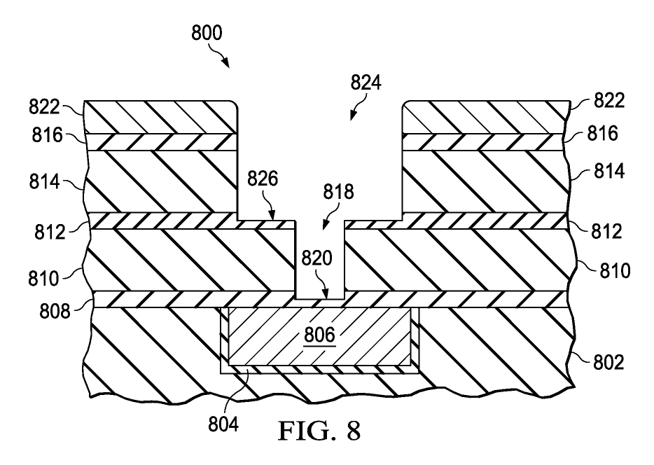

FIG. 8 is a cross-section of interconnects in an integrated circuit implementing this invention in a trench etch stop layer, shown here as fabricated in a via-first process sequence. An integrated circuit (800) includes a lower inter-level dielectric (ILD) (802), often composed of low-k material, in which has been fabricated a lower metal interconnect line including a lower metal liner (804) and lower metal fill (806), typically copper. Over the lower inter-level dielectric (802) and metal interconnect line is deposited a via etch stop layer (808). Over the via etch stop layer is deposited an upper inter-level dielectric (upper ILD) (810), also often composed of low-k material. Over the upper ILD (810) is deposited a trench etch stop layer (812), including a SiC containing film generated according to an embodiment of the instant invention. Over the trench etch stop layer (812) is deposited an intra-metal dielectric (IMD) (814), also often composed of low-k material, followed by deposition of an optional hard mask layer (816). A via hole (818) has been etched through the hard mask layer (816), if present, IMD (814), trench etch stop layer (812) and upper ILD (810), forming a recess (820) in the via etch stop layer (808). Trench regions are defined by depositing photoresist (822) a top surface of the hard mask layer (816), if present, or IMD (814), if the hard mask layer is not present, and applying known photolithographic techniques. A trench (824) is etched through the hard mask layer, if present, and IMD (814), forming a recess (826) in the trench etch stop layer (812). There are several advantages to using a trench etch stop layer incorporating a SiC containing film generated according to this invention. A first advantage is the SiC containing film does not contribute to resist poisoning, unlike films containing nitrogen, which are typically employed in interconnect fabrication. Another advantage is the superior etch rate selectivity relative to common inter-level and intra-metal dielectrics, especially low-k dielectrics, as discussed above, allows a thinner trench etch stop layer, which reduces lateral capacitive coupling between adjacent metal lines. In another embodiment, a trench etch stop layer may be composed solely of SiC as generated according to an embodiment of the instant invention. It will be apparent to practitioners of integrated circuit fabrication that the embodiments of a SiC containing film generated according to this invention in a trench etch stop layer, as related here, can be implemented in any level of interconnect in an integrated circuit.

What is claimed is:

1. A method of forming an integrated circuit, comprising the steps of:
providing a substrate;
forming a transistor in the substrate;
forming a first electrically insulating layer over the transistor;
forming a second electrically insulating layer over the first electrically insulating layer; and
forming a first layer of a silicon carbide containing film over the second electrically insulating layer, said silicon carbide containing film being formed by a process comprising the steps of:
positioning the substrate in a plasma reactor;
flowing 100 to 2000 sccm (standard cubic centimeters per minute) of hydrogen gas into said plasma reactor;
generating a plasma comprising the hydrogen gas in the plasma reactor.

2. The method of claim 1, further comprising the steps of:
forming a first layer of photoresist over said first layer of said silicon carbide containing film;
patterning the first layer of photoresist to define a first set of via regions;
etching said first layer of said silicon carbide containing film in the first set of via regions; and
etching said second electrically insulating layer in the first set of via regions.

3. The method of claim 2, further comprising the steps of
forming a third electrically insulating layer over said transistor;
forming a second layer of said silicon carbide containing film over the third electrically insulating layer;
forming a second layer of photoresist over the second layer of said silicon carbide containing film;
patterning the second layer of photoresist to define a first set of metal interconnect trench regions;
etching the second layer of said silicon carbide containing film in the first set of metal interconnect trench regions; and
etching the third electrically insulating layer in the first set of metal interconnect trench regions.

4. The method of claim 3, further comprising the steps of:
forming a third layer of said silicon carbide containing film over said transistor;
forming a fourth electrically insulating layer over the third layer of said silicon carbide containing film;
forming a third layer of photoresist over the fourth electrically insulating layer;
patterning the third layer of photoresist to define a second set of via regions; and
etching the fourth electrically insulating layer in the second set of via regions, wherein the third layer of said silicon carbide containing film is exposed in the second set of via regions.

5. The method of claim 4, further comprising the steps of:
forming a fifth electrically insulating layer over said transistor;
forming a fourth layer of said silicon carbide containing film over the fifth electrically insulating layer;
forming a sixth electrically insulating layer over the fourth layer of said silicon carbide containing film;
forming a fourth layer of photoresist over the sixth electrically insulating layer;
patterning the fourth layer of photoresist to define a second set of metal interconnect trench regions; and
etching the sixth electrically insulating layer in the second set of metal interconnect trench regions, wherein the fourth layer of said silicon carbide containing film is exposed in the second set of metal interconnect trench regions.

6. The method of claim 5, further comprising the steps of:
forming a seventh electrically insulating layer over said transistor;
forming a fifth layer of said silicon carbide containing film over the seventh electrically insulating layer;
etching the fifth layer of said silicon carbide containing film in a third set of metal interconnect trench regions;
etching the seventh electrically insulating layer in the third set of metal interconnect trench regions;
depositing liner metal and copper metal over the fifth layer of said silicon carbide containing film and in the third set of metal interconnect trench regions; and
selectively removing the liner metal and copper metal from a top surface of the fifth layer of said silicon carbide containing film.

7. A method of forming an integrated circuit, comprising the steps of:
providing a substrate;
forming a transistor in the substrate;
forming a first electrically insulating layer over the transistor;
forming a first layer of a silicon carbide containing film over the first electrically insulating layer, said silicon carbide containing film being formed by a process comprising the steps of:
positioning the substrate in a plasma reactor;
flowing 100 to 2000 sccm (standard cubic centimeters per minute) of hydrogen gas into said plasma reactor;
generating a plasma comprising the hydrogen gas in the plasma reactor;
forming a first layer of photoresist over the first layer of said silicon carbide containing film;
patterning the first layer of photoresist to define a first set of contact regions;
etching the first layer of said silicon carbide containing film in the first set of contact regions;
etching the first electrically insulating layer in the first set of contact regions;
depositing contact metal over the first layer of said silicon carbide containing film and in the first set of contact regions; and
selectively removing the contact metal from a top surface of the first layer of said silicon carbide containing film.

8. The method of claim 7, further comprising the steps of:
forming a second electrically insulating layer over the said transistor;
forming a second layer of said silicon carbide containing film over the second electrically insulating layer,
forming a second layer of photoresist over the second layer of said silicon carbide containing film;
patterning the second layer of photoresist to define a first set of via regions;
etching the second layer of said silicon carbide containing film in the first set of via regions; and
etching the second electrically insulating layer in the first set of via regions.

9. The method of claim 8, further comprising the steps of:
forming a third electrically insulating layer over said transistor;
forming a third layer of said silicon carbide containing film over the third electrically insulating layer;
forming a third layer of photoresist over the third layer of said silicon carbide containing film;
patterning the third layer of photoresist to define a first set of metal interconnect trench regions;
etching the third layer of said silicon carbide containing film in the first set of metal interconnect trench regions; and
etching the third electrically insulating layer in the first set of metal interconnect trench regions.

10. The method of claim 9, further comprising the steps of:
forming a fourth layer of said silicon carbide containing film over said transistor;
forming a fourth electrically insulating layer over the fourth layer of said silicon carbide containing film;
forming a fourth layer of photoresist over the fourth electrically insulating layer;
patterning the fourth layer of photoresist to define a second set of via regions; and
etching the fourth electrically insulating layer in the second set of via regions, wherein the fourth layer of said silicon carbide containing film is exposed in the second set of via regions.

11. The method of claim 10, further comprising the steps of:
forming a fifth electrically insulating layer over said transistor;
forming a fifth layer of said silicon carbide containing film over the fifth electrically insulating layer;
etching the fifth layer of said silicon carbide containing film in a second set of metal interconnect trench regions;
etching the fifth electrically insulating layer in the second set of metal interconnect trench regions;
depositing liner metal and copper metal over the fifth layer of said silicon carbide containing film and in the second set of metal interconnect trench regions; and
selectively removing the liner metal and copper metal from a top surface of the fifth layer of said silicon carbide containing film.

12. The method of claim 11, further comprising the steps of:
forming a sixth electrically insulating layer over said transistor;
forming a sixth layer of said silicon carbide containing film over the sixth electrically insulating layer;
forming a seventh electrically insulating layer over the sixth layer of said silicon carbide containing film;
forming a sixth layer of photoresist over the seventh electrically insulating layer;
patterning the sixth layer of photoresist to define a third set of metal interconnect trench regions; and
etching the seventh electrically insulating layer in the third set of metal interconnect trench regions, wherein the sixth layer of said silicon carbide containing film is exposed in the third set of metal interconnect trench regions.

13. A method of forming an integrated circuit, comprising the steps of:
providing a substrate;
forming a transistor in the substrate;
forming a first electrically insulating layer over the transistor;
forming a first layer of a silicon carbide containing film over the first electrically insulating layer, said silicon carbide containing film being formed by a process comprising the steps of:
positioning the substrate in a plasma reactor;
flowing 100 to 2000 sccm (standard cubic centimeters per minute) of hydrogen gas into said plasma reactor;
generating a plasma comprising the hydrogen gas in the plasma reactor;
forming a first layer of photoresist over the first layer of said silicon carbide containing film;
patterning the first layer of photoresist to define a first set of contact regions;
etching the first layer of said silicon carbide containing film in the first set of contact regions;
etching the first electrically insulating layer in the first set of contact regions;

14. The method of claim 13, further comprising the steps of:
forming a second electrically insulating layer over the said transistor;
forming a second layer of said silicon carbide containing film over the second electrically insulating layer,
forming a second layer of photoresist over the second layer of said silicon carbide containing film;
patterning the second layer of photoresist to define a first set of via regions;
etching the second layer of said silicon carbide containing film in the first set of via regions; and
etching the second electrically insulating layer in the first set of via regions.

15. The method of claim 14, further comprising the steps of:
forming a third electrically insulating layer over said transistor;
forming a third layer of said silicon carbide containing film over the third electrically insulating layer;
forming a third layer of photoresist over the third layer of said silicon carbide containing film;
patterning the third layer of photoresist to define a first set of metal interconnect trench regions;
etching the third layer of said silicon carbide containing film in the first set of metal interconnect trench regions; and
etching the third electrically insulating layer in the first set of metal interconnect trench regions.

16. The method of claim 15, further comprising the steps of:
forming a fourth layer of said silicon carbide containing film over said transistor;
forming a fourth electrically insulating layer over the fourth layer of said silicon carbide containing film;
forming a fourth layer of photoresist over the fourth electrically insulating layer;
patterning the fourth layer of photoresist to define a second set of via regions; and
etching the fourth electrically insulating layer in the second set of via regions, wherein the fourth layer of said silicon carbide containing film is exposed in the second set of via regions.

17. The method of claim 16, further comprising the steps of:
forming a fifth electrically insulating layer over said transistor;
forming a fifth layer of said silicon carbide containing film over the fifth electrically insulating layer;
etching the fifth layer of said silicon carbide containing film in a second set of metal interconnect trench regions;
etching the fifth electrically insulating layer in the second set of metal interconnect trench regions;
depositing liner metal and copper metal over the fifth layer of said silicon carbide containing film and in the second set of metal interconnect trench regions; and
selectively removing the liner metal and copper metal from a top surface of the fifth layer of said silicon carbide containing film.

18. The method of claim 17, further comprising the steps of:
forming a sixth electrically insulating layer over said transistor;
forming a sixth layer of said silicon carbide containing film over the sixth electrically insulating layer;
forming a seventh electrically insulating layer over the sixth layer of said silicon carbide containing film;
forming a sixth layer of photoresist over the seventh electrically insulating layer;
patterning the sixth layer of photoresist to define a third set of metal interconnect trench regions; and
etching the seventh electrically insulating layer in the third set of metal interconnect trench regions, wherein the sixth layer of said silicon carbide containing film is exposed in the third set of metal interconnect trench regions.

19. The method of claim 1 or claim 7 or claim 13, wherein said process for forming said silicon carbide containing film further comprises the steps of:
flowing tri-methyl silane gas into said plasma reactor; and
flowing helium gas into said plasma reactor.
